(19) United States
(12) Patent Application Publication
(10) Pub. No.: US 2025/0233282 A1
(43) Pub. Date: Jul. 17, 2025

(54) BUSBAR ASSEMBLY AND BATTERY MODULE INCLUDING THE SAME

(71) Applicant: SK ON CO., LTD., Seoul (KR)

(72) Inventors: Ye Eun KIM, Daejeon (KR); Yun Joo NOH, Daejeon (KR); Jun Seo YOON, Daejeon (KR); Deok Ho NAM, Daejeon (KR)

(21) Appl. No.: 19/021,207

(22) Filed: Jan. 15, 2025

(30) Foreign Application Priority Data
Jan. 15, 2024 (KR) 10-2024-0005899

(51) Int. Cl. H01M 50/519; H01M 10/48; H01M 50/507; H01M 50/569; H01M 50/586; H05K 1/02

(52) U.S. Cl. CPC H01M 50/519; H01M 10/486; H01M 50/507; H01M 50/569; H01M 50/586; H05K 1/028

(57) ABSTRACT

A battery module includes a cell stack including a plurality of battery cells, a plurality of busbars electrically connected to the plurality of battery cells, a support frame supporting the plurality of bus bars, and a circuit board electrically connected to the plurality of busbars. The circuit board includes a plurality of extension portions extending in different directions, and at least one overlapping portion in which at least two extension portions, among the plurality of extension portions, overlap.

### CROSS-REFERENCE TO RELATED APPLICATION(S)

This patent document claims the priority and benefits of Korean Patent Application No. 10-2024-0005899 filed on Jan. 15, 2024, the disclosure of which is incorporated herein by reference in its entirety.

### TECHNICAL FIELD

The disclosure and implementations disclosed in this patent document generally relate to a busbar assembly and a battery module including the same.

### BACKGROUND

Secondary batteries, unlike primary batteries, may be charged and discharged, and may be applied to devices within various fields such as digital cameras, mobile phones, laptops, hybrid cars, and electric vehicles. Secondary batteries include nickel-cadmium batteries, nickel-metal hydride batteries, nickel-hydrogen batteries, lithium secondary batteries, and the like.

These secondary batteries are manufactured as flexible pouch-type battery cells or rigid prismatic or cylindrical can-type battery cells, d are used by electrically connecting multiple battery cells. At this time, multiple battery cells form a cell stack in a stacked form and are disposed inside a housing to form a battery device such as a battery module or a battery pack.

To sense operating status values of the battery device, the battery device is equipped with circuit boards to which various sensing members are connected. For example, a battery device may include a circuit board to which a voltage sensor is connected, and a circuit board to which a temperature sensor is connected.

As the structure of a battery device becomes larger and more complex, there is a concern that connection noise may occur between circuit boards to which sensing members are connected. In addition, when manufacturing circuit boards to fit various shapes of battery devices, a manufacturing efficiency of a circuit board decreases and a decrease in yield due to waste of manufacturing materials may be problematic.

### SUMMARY

The present disclosure may be implemented in some embodiments to provide a busbar assembly including an integrated circuit board to which a sensing terminal for collecting voltage data and a temperature sensor for collecting temperature data are connected, and a battery module including the same.

In some embodiments, a battery module includes a cell stack including a plurality of battery cells; a plurality of busbars electrically connected to the plurality of battery cells; a support frame supporting the plurality of bus bars; and a circuit board electrically connected to the plurality of busbars. The circuit board includes a plurality of extension portions extending in different directions; and at least one overlapping portion in which at least two extension portions, among the plurality of extension portions, overlap.

In the at least one overlapping portion, the circuit board may have a folded shape folded at least once.

The plurality of extension portions may include a first extension portion disposed above the cell stack and extending in a first direction; and a second extension portion disposed above the cell stack and extending in a second direction different from the first direction.

In the first extension portion, a first surface of the circuit board may face the support frame, and in the second extension portion, a second surface of the circuit board, an opposite surface to the first surface, may face the support frame.

The at least one overlapping portion may further include a first overlapping portion configured such that the first extension portion and the second extension portion overlap.

In the first overlapping portion, the first extension portion and the second extension portion may face each other in a direction perpendicular to the first surface.

A circuit layer may be disposed on the first surface of the circuit board, and an insulating layer may be disposed on the second surface of the circuit board.

The plurality of extension portions may further include a third extension portion to which a sensing terminal electrically connected to the plurality of busbars is connected.

The at least one overlapping portion may further include a second overlapping portion in which the second extension portion and the third extension portion overlap.

In the second overlapping portion, the circuit board may overlap three or more times.

The support frame may include a plurality of busbar frames to which the plurality of busbars are coupled; and a connecting frame connecting the plurality of busbar frames, and the second overlapping portion may face one of the plurality of busbar frames.

The sensing terminal may include a first coupling portion coupled with the circuit board and a second coupling portion coupled with at least one of the plurality of busbars.

The first coupling portion may be soldered to the circuit board, and the second coupling portion may be welded to at least one of the plurality of busbars.

The circuit board may further include a temperature sensor disposed on the third extension portion.

The support frame may further include an avoidance portion avoiding the temperature sensor, and at least a portion of the temperature sensor may be accommodated in the avoidance portion and may face the cell stack.

The battery module may further include an insulating member covering the overlapping portion of the circuit board and formed of an insulating material.

The circuit board may be a sensing circuit board to which a sensing member is connected, the sensing member including at least one of a temperature sensor for measuring temperature or a sensing terminal connected to the plurality of busbars and measuring voltage.

In some embodiments, a busbar assembly includes a support frame; at least one busbar coupled to the support frame; and a circuit board disposed in the support frame and electrically connected to the at least one busbar. The circuit board includes a first extension portion and a second extension portion extending in different directions from the support frame; a third extension portion extending from at least one of the first extension portion or the second extension portion and connected to the at least one busbar; and at least one overlapping portion provided by overlapping any two of the first extension portion, the second extension portion, or the third extension portion.

The support frame may include a plurality of busbar frames to which the at least one busbar is coupled and a connecting frame connecting the plurality of busbar frames to each other. The first extension portion and the second extension portion may be disposed on the connecting frame, and the third extension portion may be disposed on at least one of the plurality of busbar frames.

The third extension portion may be extended in parallel with either the first extension portion or the second extension portion.

### BRIEF DESCRIPTION OF DRAWINGS

Certain aspects, features, and advantages of the present disclosure are illustrated by the following detailed description with reference to the accompanying drawings.

FIG. 1 is a perspective view of a battery module.

FIG. 2 is an exploded perspective view of a battery module.

FIG. 3 is an example configuration of a cell stack.

FIG. 4 is a reference diagram illustrating a combined appearance of a busbar assembly and a circuit board.

FIG. 5 is a reference diagram illustrating a configuration of a circuit board.

FIG. 6 is a reference diagram illustrating a configuration of an adhesive material disposed between a circuit board and a busbar assembly.

FIG. 7 is an example cross-sectional view of a circuit board.

FIG. 8 is an example diagram illustrating a structure of a first overlapping portion of a circuit board.

FIG. 9 is an example diagram illustrating a structure

of a first overlapping portion of a circuit board.

FIG. 10 is an example diagram illustrating a structure of a second overlapping portion of a circuit board.

FIG. 11 is a reference diagram illustrating a sensing terminal connected to a circuit board and a busbar.

FIG. 12 is a reference diagram illustrating an insulating member protecting an overlapping portion of a circuit board.

### DETAILED DESCRIPTION

Features of the present disclosure disclosed in this patent document are described by example embodiments with reference to the accompanying drawings.

Prior to the detailed description of example embodiments of the present disclosure, terms or words used in the present specification and claims should not be construed as being limited to their usual or dictionary meanings, and should be interpreted with meaning and concept consistent with the technical idea of the present disclosure, based on the principle that the inventor may appropriately define the concept of terms to explain his or her invention in the best way. Therefore, the embodiments described in this specification and the configurations illustrated in the drawings are only the example embodiments and do not represent all of the technical ideas of the present disclosure, and therefore, it should be understood that there may be various equivalents and modified examples that may replace the same.

The same reference numbers or symbols in respective drawings indicate parts or components that perform substantially the same For convenience of function. explanation and understanding, the same reference numbers or symbols may be used in different embodiments. For example, even if a plurality of drawings illustrate components having the same reference numbers, the plurality of drawings do not all represent one embodiment.

In the following description, singular expressions include plural expressions unless the context clearly dictates otherwise. Terms such as “include,” “configure” and the like are intended to designate the presence of features, numbers, steps, operations, components, parts, or combinations thereof described in the specification, and should be understood as not precluding the presence or addition of one or more other features, numbers, steps, operations, components, parts, or combinations thereof.

In addition, in the following description, expressions such as upper side, upper portion, lower, bottom, side, front, rear, and the like are expressed based on the direction illustrated in the drawing, and it should be noted in advance that if the direction of the object is changed, it may be expressed differently.

Additionally, in the present specification and claims, terms including ordinal numbers such as “first,” “second,” and the like may be used to distinguish between components. These ordinal numbers are used to distinguish identical or similar components from each other, and the meaning of the term should not be interpreted limitedly due to the use of these ordinal numbers. For example, components combined with these ordinal numbers should not be interpreted as having a limited order of use or arrangement based on the number. If necessary, respective ordinal numbers may be used interchangeably.

Hereinafter, embodiments will be described with reference to the attached drawings. However, the spirit of the present disclosure is not limited to the presented embodiments. For example, a person skilled in the art who understands the spirit of the present disclosure may suggest other embodiments included within the scope of the spirit of the present disclosure by adding, changing, or deleting components, but this will also be included within the scope of the spirit of the present disclosure. The shapes and sizes of elements in the drawings may be exaggerated for a clearer explanation.

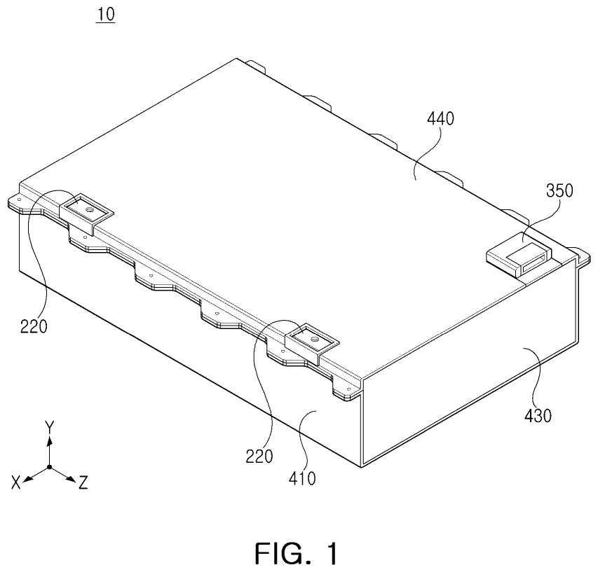

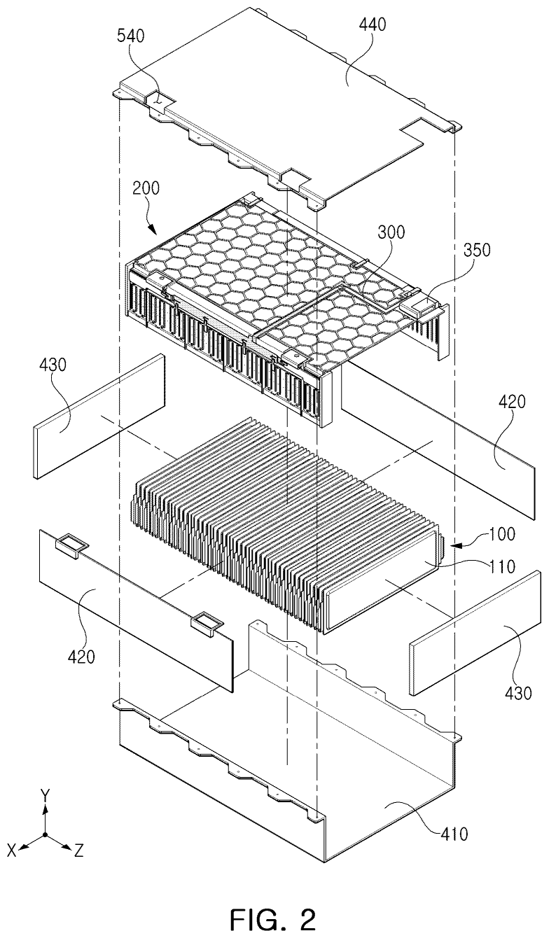

Referring to FIGS. 1 and 2, a battery module 10 according to embodiments will be described.

FIG. 1 is a perspective view of a battery module 10. FIG. 2 is an exploded perspective view of a battery module 10.

The battery module 10 may include a housing 410 having a plurality of battery cells 110 and an internal space accommodating the plurality of battery cells 110, a busbar assembly 200 electrically connected to the battery cells 110, and an end cover 430 coupled to the housing 410.

The plurality of battery cells 110 accommodated in the battery module 10 may be stacked in one direction (for example, the Z-axis direction of FIG. 2) to form at least a portion of a cell stack 100. Each battery cell 110 may output or store electrical energy. In the cell stack 100, the battery cells 110 may be electrically connected to each other.

As a large number of battery cells 110 are stacked in the battery module 10, there is a concern that damage may be inflicted to other battery cells due to an event situation (for example, a situation in which high-temperature gas or flame is generated, or a situation in which a battery cell expands abnormally) occurring in one battery cell 110. To prevent this, the battery module 10 may further include a protective member disposed between the battery cells 110.

For example, the protective member may include a material capable of blocking heat to prevent heat transmission between neighboring battery cells 110. Alternatively, the protective member may include a material capable of applying surface pressure to the battery cell 110 to perform a function of suppressing expansion of the battery cell 110.

A plurality of battery cells 110 included in the cell stack 100 may be electrically connected to each other through a busbar assembly 200. The busbar assembly 200 may be disposed so that at least a portion thereof faces the cell stack 100 in a direction perpendicular to the cell stacking direction.

The busbar assembly 200 may include a busbar 210 that electrically connects one battery cell 110 to another battery cell 110, and a support frame 230 that supports the busbar 210.

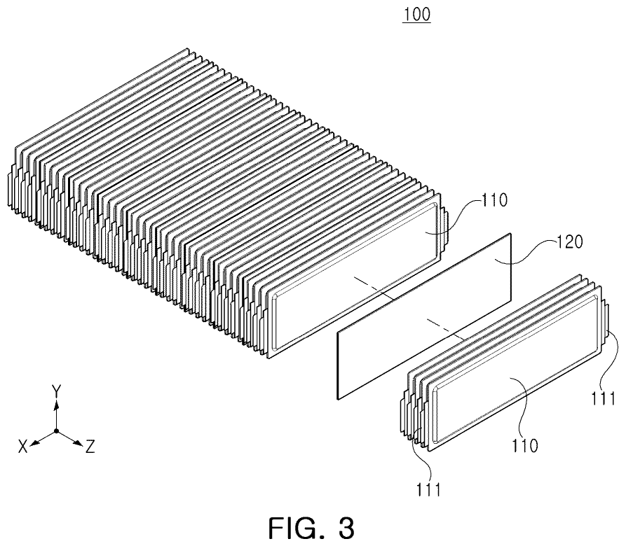

The busbar 210 may be formed of a conductive material and serves to electrically connect a plurality of battery cells 110 to each other. The busbar 210 may be electrically connected to a lead tab (for example, 111 of FIG. 3) of the battery cell 110. Various welding methods, including laser welding or the like, may be applied to the connection between the busbar 210 and the lead tab (111 of FIG. 3). However, the connection method is not limited to welding, and any connection method that may electrically conduct two metallic materials may be used.

Some of the busbars 210 of the busbar assembly 200 may have terminal portions 220 that may be electrically connected to a circuit outside the battery module 10. The terminal portions 220 may be exposed to the outside of the battery module 10 through an opening 540 of the housing 410.

The busbar 210 may be fixed to the support frame 230. At least a portion of the support frame 230 may be formed of an insulating material to prevent an unintended short circuit from occurring between the plurality of busbars 210. The support frame 230 may face at least one side of the cell stack.

The battery module 10 may further include a circuit board 300 to which one or more sensing members capable of detecting the operating status, environmental status, and the like of the battery cells 110 are connected. For example, the sensing members may include a temperature sensor 370 for measuring the temperature of an adjacent portion (which may mean at least one of the battery cells 110 or an internal space of the battery module 10), a sensing terminal 360 for measuring the voltage of the battery cells 110, or the like.

Meanwhile, even if it is referred to as ‘sensing members’ in this specification, this is an expression for convenience and may refer to ‘one or more sensing members’.

In addition, in this specification, one or more sensing members connected to the circuit board 300 may be collectively referred to as a “sensor unit.” In detail, the sensor unit may refer to one or more sensing members.

In this case, the sensor unit (sensing member) may include at least one of various sensing members (sensors) as well as the temperature sensor 370 and the sensing terminal 360 described above. For example, the sensing member may include any of a pressure sensor, a humidity sensor, a shock detection sensor, or the like, as long as it may measure information values for at least one of the battery cell 110 or the battery module 10.

In addition, the circuit board 300 described in the present disclosure may refer to a sensing circuit board (or a circuit board for sensing) as the circuit board 300 to which one or more sensing members described above are connected.

The circuit board 300 may be coupled to the busbar assembly 200. For example, the circuit board 300 may be coupled to the support frame 230 so that the position thereof may be fixed. Meanwhile, since the circuit board 300 is coupled to the busbar assembly 200 as described below, the busbar assembly 200 to which the circuit board 300 is coupled may be conveniently referred to as a “busbar assembly 200.”

Information sensed by the sensing members connected to the circuit board 300 may be transmitted to an external electronic element (for example, a Battery Management System (BMS)) of the battery module 10 through a connector 350 electrically connected to the circuit board 300. In addition, the sensing members connected to the circuit board 300 may receive information from the outside of the battery module 10 through a connector electrically connected to the circuit board 300.

At least a portion of the circuit board 300 may be formed of a flexible printed circuit board (FPCB). Accordingly, at least a portion of the circuit board 300 may be configured to be bendable or foldable.

The housing 410 provides an internal space in which one or more cell stacks 100 may be accommodated. The housing 410 may be formed of a material having a predetermined rigidity to protect the cell stacks 100 and other electrical components accommodated in the internal space from external impact. For example, the housing 410 may include a metal material such as aluminum.

An upper cover 440 may be coupled to the upper side of the housing 410 to protect the upper side of the cell stack 100. However, the structure of the housing 410 is not limited thereto, and may have any shape as long as it has an internal space in which at least one cell stack 100 may be accommodated. For example, the housing 410 may be formed integrally with the upper cover 440 and configured as an integral monoframe with both sides open.

An end cover 430 may be coupled to an open side of the housing 410. For example, as illustrated in FIG. 2, the end covers 430 may be provided as a pair and coupled to both sides of the housing 410, respectively.

The end covers 430 may be coupled to the housing 410 to form the exterior of the battery module 10 together with the housing 410. The end covers 430 may include a metal material such as aluminum, like the housing.

To prevent electrical short-circuiting between the busbar assembly 200 and the housing 410 and the upper cover 440, the battery module 10 may include an insulating cover 420. For example, the insulating cover 420 may be positioned between the busbar assembly 200 and the housing 410, to face the busbar assembly 200. The insulating cover 420 may include an insulating material, and thus may block electrical connection between the busbar assembly 200 and the housing 410. For example, the insulating cover 420 may be formed of a plastic injection molded product including polypropylene, modified polyphenylene oxide (MPPO), or the like. However, the material of the insulating cover 420 is not limited thereto. As the insulating cover 420 is disposed, an electrical short circuit may be prevented from occurring between the cell stack 100 and the housing 410, or between the busbar 210 and the housing 410.

A heat dissipation member (not illustrated) may be disposed between the cell stack 100 and the housing 410. The heat dissipation member (not illustrated) may be disposed so that one side is in contact with the cell stack 100, and the other side opposite to the one side is in contact with the housing 410. The heat dissipation member (not illustrated) may be provided as a thermal adhesive. The heat dissipation member (not illustrated) may fill the space between the cell stack 100 and the housing 410 to enable more active heat transfer through conduction. Accordingly, the heat dissipation efficiency of the battery module 10 may be increased.

Hereinafter, the configuration of the cell stack 100 will be described in more detail with reference to FIG. 3.

FIG. 3 is an example configuration of the cell stack 100. The cell stack 100 described in FIG. 3 corresponds to the cell stack 100 described previously through FIG. 1 and FIG. 2, and thus redundant description may be omitted.

The cell stack 100 may include one or more battery cells 110. The battery cell 110 may be configured to convert chemical energy into electrical energy and supply power to an external circuit, or may be configured to receive power from the outside and convert electrical energy into chemical energy to store electricity. For example, the battery cell 110 may be configured as a nickel metal hydride (Ni-MH) battery or a lithium ion (Li-ion) battery that may be charged and discharged, but is not limited thereto. In embodiments, as the battery cells 110, a plurality of battery cells 110 may be electrically connected to each other while being stacked side by side.

The battery cell 110 included in the cell stack 100 may be a pouch-type battery cell. For example, referring to FIG. 3, the battery cell 110 may be configured such that an electrode assembly including a plurality of electrode plates is accommodated within the pouch, and a lead tab is exposed on one side of the pouch. The lead tab of the battery cell 110 may be electrically connected to the busbar 210 of the busbar assembly 200 described above.

However, a detailed structure or shape of the battery cell 110 is not limited to that illustrated in the drawing. For example, the battery cell may also be configured as a cylindrical battery cell or a prismatic battery cell.

The cell stack 100 may further include a protective member disposed between the battery cells 110.

The protective member may include a material capable of blocking heat and may serve as blocking heat propagation between battery cells 110. For example, the protective member may include at least one of mica sheet, silicate, graphite, alumina, ceramic wool (or super wool), and aerogel.

Alternatively, the protective member may include a material capable of compressing the battery cell 110 with a predetermined elasticity and may be configured to apply surface pressure to the battery cell 110. Accordingly, the protective member may prevent the battery cell 110 from expanding excessively. For example, the protective member may include at least one of polyurethane, silicone, and rubber (EPDM).

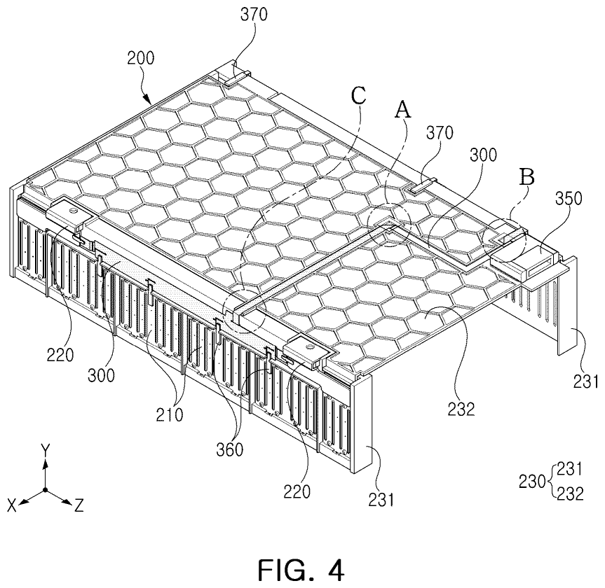

Hereinafter, the busbar assembly 200 and the circuit board 300 included in the battery module 10 will be described in detail with reference to FIGS. 4 to 10.

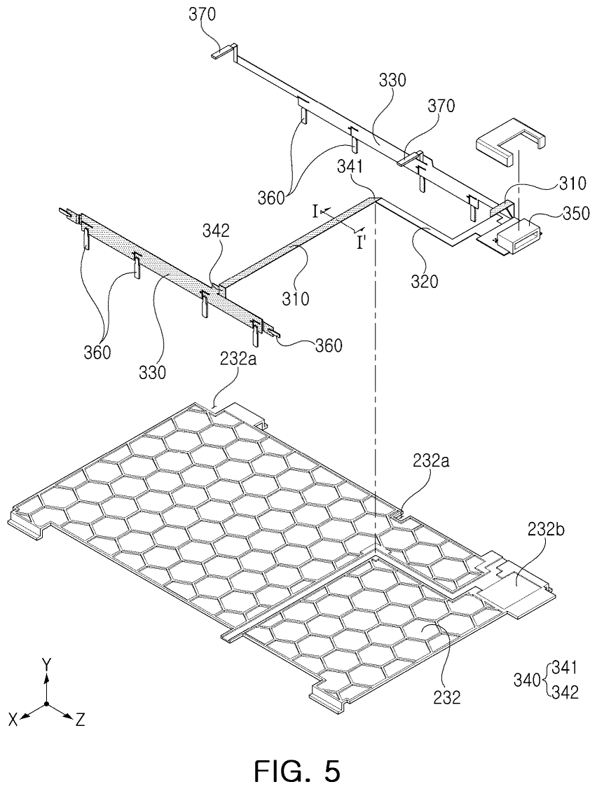

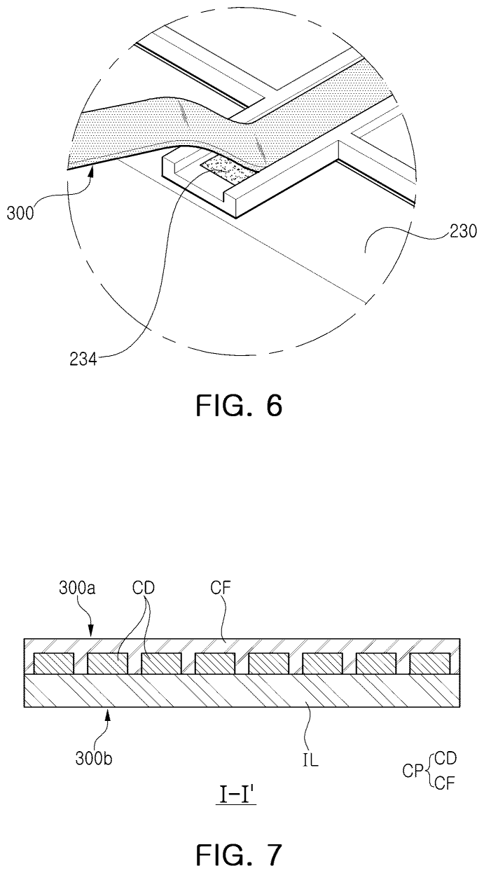

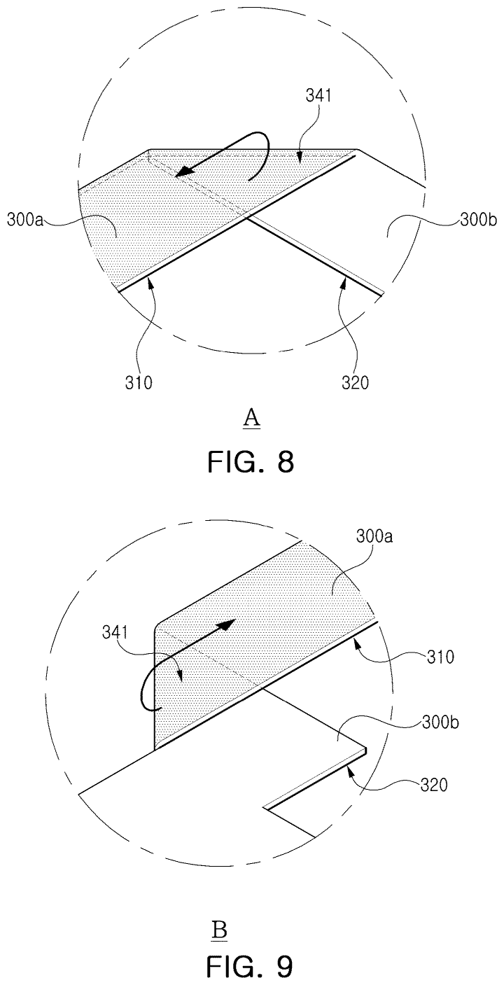

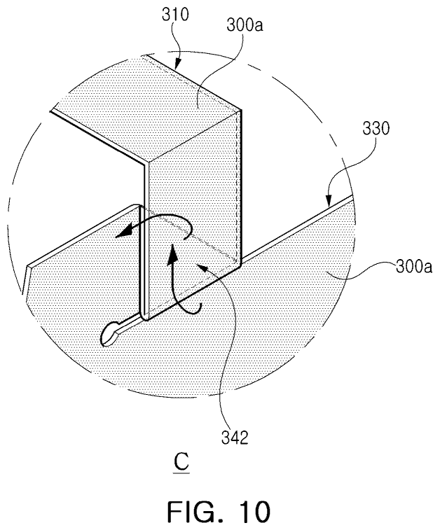

FIG. 4 is a reference diagram illustrating the appearance of combination of the busbar assembly 200 and the circuit board 300. FIG. 5 is a reference diagram illustrating the configuration of the circuit board 300. FIG. 6 is a reference diagram illustrating the appearance of the adhesive member 234 being disposed between the circuit board 300 and the busbar assembly 200. FIG. 7 is an example cross-sectional view of the circuit board 300. FIG. 8 illustratively shows a structure of a first overlapping portion 341 of the circuit board 300. FIG. 9 illustratively shows a structure of a first overlapping portion 341 of the circuit board 300. FIG. 10 illustratively shows a structure of a second overlapping portion 342 of the circuit board 300.

The battery module 10 and components thereof described in FIGS. 4 to 10 correspond to the battery module 10 and the components thereof described in FIGS. 1 to 3, and thus any redundant description may be omitted.

A plurality of battery cells 110 included in a battery module 10 may be electrically connected to each other through a busbar assembly 200.

The busbar assembly 200 may include a conductive busbar 210 electrically connected to the battery cell 110 and a support frame 230 supporting a busbar 210.

The busbar 210 may be disposed in plural on the support frame 230 and may be arranged side by side in the cell stacking direction (for example, the Z-axis direction).

The support frame 230 may structurally support the busbar 210 even under external impact or vibration conditions. For example, the support frame 230 may include a plastic material that is lightweight and has excellent mechanical strength, such as polypropylene, polybutylene terephthalate, or modified polyphenylene oxide (MPPO), and thus may structurally support the busbar 210 while ensuring insulation.

The busbar 210 may be fixed to the support frame 230 in various manners. For example, the busbar 210 may be fixed to the support frame 230 by a heat-melting process or an insert injection process.

The support frame 230 may include a plurality of busbar frames 231 on which the busbar 210 is disposed, and a connecting frame 232 that connects the busbar frames 231. For example, referring to FIG. 4, the busbar assembly 200 may include a plurality of busbar frames 231 facing each other, and a connecting frame 232 connected to all of the plurality of busbar frames 231. Meanwhile, although the present disclosure refers to a plurality of busbars 210, it will be said that they all belong to the present disclosure as long as one or more busbars 210 are included. For example, one busbar 210 may be provided.

The circuit board 300 may be disposed so that at least a portion thereof faces the support frame 230. For example, referring to FIG. 4, the circuit board 300 may be disposed to face the support frame 230 across the busbar frame 231 and the connecting frame 232.

At least a portion of the circuit board 300 may be fixed to the support frame 230. For example, referring to FIG. 6, an adhesive member 234 including an adhesive material may be disposed between the bottom surface of the circuit board 300 and the support frame 230, to fix the circuit board 300 to the support frame 230. For example, the adhesive member 234 may be composed of an adhesive plate, sheet, film, or the like. However, the circuit board 300 and the support frame 230 may be applied with various fixing methods (for example, insertion coupling, bolting coupling, or the like) in addition to the fixing method by the adhesive material 234 described above.

At least a portion of the circuit board 300 may be formed of a flexible printed circuit board (FPCB). Accordingly, a portion of the circuit board 300 formed of the FPCB may be configured to be bent or folded.

At least a portion of the circuit board 300 may be formed of a single-sided flexible printed circuit board (Single Side FPCB). For example, referring to FIG. 5 and FIG. 7, at least a portion of the circuit board 300 may be formed of a single-sided printed circuit board in which a circuit layer CP is disposed on a first surface 300a and an insulating layer IL is disposed on a second surface 300b opposite to the first surface 300a.

Referring to FIG. 7, the circuit layer CP of the circuit board 300 is composed of a conductive metal line CD and a coating portion CF that surrounds at least one side of the metal line CD, and may form a first surface 300a of the circuit board 300. The insulating layer IL of the circuit board 300 is formed of an insulating material, and may form a second surface 300b opposite to the first surface 300a of the circuit board 300. A conductive metal line CD may be disposed on the upper portion of the insulating layer IL.

Since the circuit layer CP is disposed on the first surface 300a of the circuit board 300, electronic components (for example, sensing terminals or connectors) may be disposed on the first surface 300a and electrically connected to the circuit board 300. Electrical connections between electronic components and the circuit layer CP may be obtained in various manners other than the soldering method.

Meanwhile, the detailed cross-sectional structure of the circuit board 300 is not limited to that illustrated in FIG. 7. For example, the circuit layer CP may further include a peeling prevention layer (not illustrated) that prevents peeling of the conductive metal line CD and the insulating layer IL.

In embodiments, the circuit board 300 of the battery module 10 may include a plurality of extension portions 310, 320 and 330 extending in different directions, and one or more overlapping portions 340 formed by overlapping any two of the plurality of extension portions 310, 320 and 330. In this case, ‘overlapping’ indicates that the circuit board 300 is bent or folded so that portions of the circuit board 300 overlap. For example, FIGS. 8 to 10 are enlarged views of portions A to C of FIG. 4, respectively, and illustrate multiple overlapping portions 341 and 342 formed on a circuit board 300.

Referring to FIG. 5, the circuit board 300 may

include a first extension portion 320 connected to a connector 350, and a second extension portion 310 connected to the first extension portion 320 and extending in a different direction from the first extension portion 320.

The connector 350 may be seated on a connector mounting portion 232b of the connecting frame 232, and may be electrically connected to the circuit board 300 to function as a passage for exchanging electrical signals between the circuit board 300 and an external component (for example, BMS) of the battery module 10.

The first extension portion 320 and the second extension portion 310 may extend in different directions. For example, the first extension portion 320 may extend in the first direction (Z-axis direction), the stacking direction of the battery cell 110, and the second extension portion 310 may extend in the second direction (X-axis direction) which is perpendicular to the first direction (Z-axis direction). However, the extension portion directions of the first extension portion 320 and the second extension portion 310 are not limited to those described above, and may be appropriately changed according to an overall structure of the battery module 10.

The first extension portion 320 and the second extension portion 310 may extend along one surface of the support frame 230. For example, the first extension portion 320 and the second extension portion 310 may extend along the upper surface of the connecting frame 232 which is disposed on the upper side of the cell stack 100.

The first extension portion 320 and the second extension portion 310 may overlap each other to form a first overlapping portion 341. Referring to FIGS. 8 and 9, the circuit board 300 may be folded to form the first overlapping portion 341, and the first extension portion 320 and the second extension portion 310 may overlap each other in the first overlapping portion 341.

In the first overlapping portion 341, the first surface 300a or the second surface 300b of the circuit board 300 may overlap one or more times. For example, referring to FIGS. 8 and 9, as the circuit board 300 is folded, the first surface 300a and the second surface 300b of the circuit board 300 overlap once in the first overlapping portion 341, respectively. Additionally, in the first overlapping portion 341, the first extension portion 320 and the second extension portion 310 may face each other and come into contact in a direction perpendicular to the first surface 300a.

The circuit board 300 may further include a third extension portion 330 on which a sensing portion, for example, one or more sensing members 360 and 370, are disposed. For example, referring to FIG. 5, the third extension portion 330 may be a portion on which a sensing terminal 360 configured to detect voltage in the circuit board 300 and a temperature sensor 370 configured to detect temperature are disposed, and may extend from the second extension portion 310. Meanwhile, in the present specification, “the sensing member detects” may encompass not only detecting a specific environmental variable value, but also measuring the magnitude of the environmental variable value as numerical data or the like, and may mean sensing. The third extension portion 330 may be fixed to a busbar frame. For example, referring to FIGS. 4 and 5, at least a portion of the third extension portion 330 may be configured to extend in the first direction (Z-axis direction), which is the cell stacking direction, along the busbar frame 231.

A second overlapping portion 342 formed by folding the circuit board 300 one or more times may be disposed between the second extension portion 310 and the third extension portion 330. The second overlapping portion 342 may be disposed to face the busbar frame 231.

In the second overlapping portion 342, the second extension portion 310 and the third extension portion 330 may overlap each other. For example, as illustrated in FIG. 10, the second overlapping portion 342 may be formed by folding the circuit board 300 two or more times.

In the second overlapping portion 342, the first surface 300a or the second surface 300b of the circuit board 300 may be overlapped two or more times. For example, in the second overlapping portion 342 illustrated in FIG. 10, the first surface 300a and the second surface 300b of the circuit board 300 may be overlapped three times each.

In embodiments, the circuit board 300 may be fixed so that the overlapping portion 340 is maintained in a folded state. For example, an adhesive member (not illustrated) may be applied to an overlapping portion of the circuit board 300 so that the circuit board 300 may be maintained in a folded state.

In embodiments, the circuit board 300 may be disposed so that the opposing surfaces of the front and rear of the overlapping portion 340 face the support frame 230. For example, in the first extension portion 320 and the second extension portion 310 that overlap each other to form the first overlapping portion 341, the first extension portion 320 may be disposed such that the first surface 300a, which is the circuit layer CP, faces the support frame 230, and the second extension portion 310 may be disposed such that the second surface 300b, which is the insulating layer IL, faces the support frame 230. For example, in this case, the first extension portion 320 may have the second surface 300b, which is the insulating layer IL, exposed upward, and the second extension portion 310 may have the first surface 300a, which is the circuit layer CP, exposed upward. For example, in the circuit board 300 illustrated in the drawing, the shaded surface may refer to the first surface 300a on which the circuit layer CP is disposed, and the non-shaded surface may refer to the second surface 300b on which the insulating layer IL is disposed.

For example, the user or the manufacturer may design the circuit board 300 to have a specific surface facing the support frame 230 and the opposite surface exposed in the upper direction of the support frame 230 by appropriately forming an overlapping portion 340 on the circuit board 300.

In the case of this overlapping portion 340 structure, the circuit board 300 may be configured as a single-sided FPCB while exposing the circuit layer CP at an appropriate location desired by the manufacturer. In detail, even if the circuit board 300 is configured as a single-sided FPCB with a lower manufacturing cost than a double-sided FPCB, the overlapping portion 340 structure may be used to cope with the complex structure of the battery module 10, thereby reducing the manufacturing cost of the battery module 10.

In the circuit board 300, when the overlapping portion 340 is fully unfolded, the directions in which the first extension portion 320, the second extension portion 310, and the third extension portion 330 extend may all be parallel. For example, when both the first overlapping portion 341 and the second overlapping portion 342 in the circuit board 300 are unfolded, the first extension portion 320 and the second extension portion 310 may be portions that extend in a straight line, and the third extension portion 330 may be a portion that extends in parallel with and adjacent to the first extension portion 320 and the second extension portion 310.

For example, the circuit board 300 according to embodiments may be manufactured so that the first extension portion 320, the second extension portion 310, and the third extension portion 330 are densely disposed, and then may be configured to be folded appropriately in response to the shape of the support frame 230, to be both seated on the busbar frames 231 on both sides. In this structure, a waste material (for example, a base material of FPCB) in the process of manufacturing the circuit board 300 may be significantly reduced, and thus, a manufacturing yield of the circuit board 300 may be increased.

In addition, since the circuit board 300 is configured to be foldable, even if the size of the battery module 10 changes and the position of the busbar frame 231 changes, the circuit board 300 may be properly formed to be seated on the busbar frame 231 at the changed position.

In addition, depending on a shape of the battery module 10, the circuit board 300 needs to be configured to extend in various directions, and since the circuit board 300 is configured to be foldable, the extension portion direction of the circuit board 300 may be set in various ways by appropriately forming the overlapping portion 340.

In embodiments, the battery module 10 may further include a sensing member connected to the circuit board 300. The sensing member may include, for example, one or more temperature sensors 370 configured to sense temperature and a plurality of sensing terminals 360 configured to sense voltage of the battery cell.

The temperature sensor 370 may be formed integrally with the circuit board 300. For example, referring to FIGS. 4 and 5, the temperature sensor 370 may be connected to the third extension portion 330 of the circuit board 300. In this manner, by forming the temperature sensor 370 integrally with the circuit board 300, a battery module 10 having a relatively simpler sensing structure may be implemented.

At least a portion of the temperature sensor 370 may be disposed to face the cell stack 100. For example, an avoidance portion 232a configured to accommodate the temperature sensor 370 is disposed in the connecting frame 232, and the temperature sensor 370 is disposed to face the cell stack 100 below the connecting frame 232 through the avoidance portion 232a to measure temperature of the battery cell 110.

The temperature information of the battery cell 110 detected through the temperature sensor 370 may be transmitted to an external component (for example, BMS) of the battery module 10 through the circuit board 300.

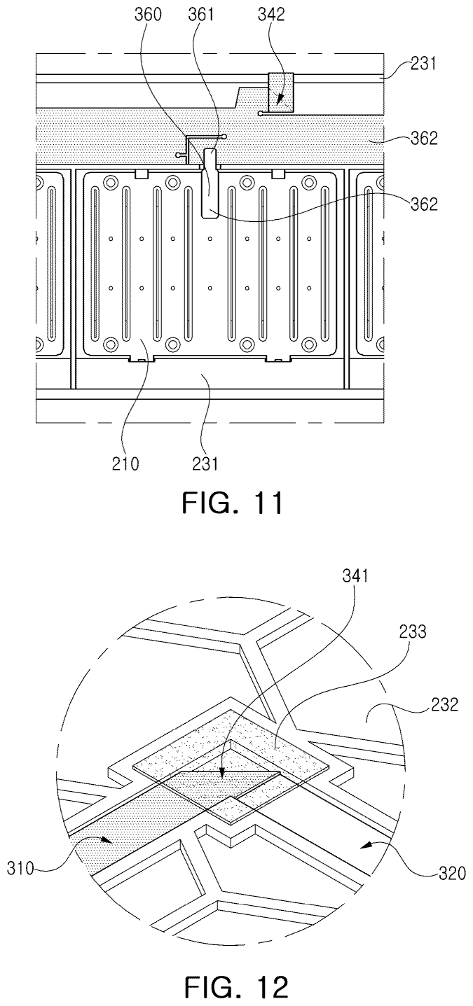

The sensing terminal 360 may be configured to be electrically connected to one or more busbars 210 and the circuit boards 300, respectively, and to detect voltage information of the cell stack 100. The connection between the sensing terminal 360, the busbar 210, and the circuit board 300 is described with reference to FIG. 11.

FIG. 11 is a reference diagram illustrating a sensing terminal 360 connected to a circuit board 300 and a busbar.

The sensing terminal 360, the circuit board 300, and the busbar described in FIG. 11 correspond to the sensing terminal 360, the circuit board 300, and the busbar described in FIGS. 1 to 10, and thus, redundant descriptions may be omitted.

The sensing terminal 360 may include a conductive metal material and be electrically connected to the busbar 210 and the circuit board 300, respectively, to perform the role of a terminal for voltage detection. Alternatively, the sensing terminal 360 may be configured as a voltage sensor that may generate a signal according to a voltage value by itself.

The sensing terminal 360 may include a first coupling portion 361 coupled to the circuit board 300 and a second coupling portion 362 coupled to the busbar 210.

The second coupling portion 362 of the sensing terminal 360 may be welded to the busbar 210. For example, the second coupling portion 362 of the sensing terminal 360 may be laser welded to the surface of the busbar 210. However, various methods other than welding may be applied as the method of coupling the sensing terminal 360 and the busbar 210.

Since the circuit board 300 may include a material having a relatively lower melting point than the busbar 210, a method other than welding may be applied for joining the sensing terminal 360 and the circuit board 300. For example, the first coupling portion 361 of the sensing terminal 360 may be soldered to the first surface 300a of the circuit board 300. The soldering may be applied using a surface mounting technology using solder paste.

Meanwhile, to strengthen the insulation performance of the folded portion of the circuit board 300, the battery module 10 may further include an insulating member 233 covering the overlapping portion of the circuit board 300. Hereinafter, this insulating member 233 will be described with reference to FIG. 12.

FIG. 12 is a reference diagram illustrating an insulating member 233 protecting the overlapping portion of the circuit board 300.

Since the circuit board 300 described in FIG. 12 corresponds to the circuit board 300 described in FIG. 1 to FIG. 11 above, redundant descriptions may be omitted.

The insulating member 233 may prevent the circuit board 300 from being short-circuited with other components (for example, housing) of the battery module 10 at the overlapping portion.

The insulating member 233 may be disposed to cover the overlapping portion 341 of the circuit board 300. For example, the insulating member 233 may be provided as a thin flat plate or film-like member that may cover the upper portion of the overlapping portion 341, and may be at least partially coupled to the connecting frame 232 to protect the overlapping portion 341.

In FIG. 12, only the insulating member 233 protecting the first overlapping portion 341 is illustrated, but the battery module 10 may further include another insulating member protecting the second overlapping portion 342. For example, the battery module 10 may include another insulating member that is at least partially connected to the busbar frame 231 and covers an upper portion of the second overlapping portion 342 to protect the second overlapping portion 342.

According to embodiments, a battery module 10 including an integrated circuit board 300 to which a sensing terminal 360 and a temperature sensor 370 are connected may be implemented.

In addition, according to embodiments, an integrated circuit board 300 may be implemented in which the first extension portion 320, the second extension portion 310, and the third extension portion 330 extending in different directions are all connected through the overlapping portion 340. Accordingly, signal noise that may occur when the first extension portion 320, the second extension portion 310, and the third extension portion 330 are configured as individual circuits and connected to each other may be prevented in advance.

In addition, since the circuit board 300 is manufactured by intensively disposing the first extension portion 320, the second extension portion 310, and the third extension portion 330, and then, the overlapping portion 340 may be appropriately configured during an assembly stage of the battery module 10, so that the circuit board 300 may be transformed into various shapes. Accordingly, a manufacturing yield of the circuit board 300 may be increased.

As set forth above, according to an embodiment, a busbar assembly or a battery module including an integrated circuit board to which a sensing terminal for collecting voltage data and a temperature sensor for collecting temperature data are connected may be implemented.

According to an embodiment, a manufacturing yield of a circuit board may be increased in manufacturing a busbar assembly or a battery module.

According to an embodiment, since a circuit board composed of a single-sided PCB may be applied, manufacturing costs of a busbar assembly or a battery module may be reduced.

Only specific examples of implementations of certain embodiments are described. Variations, improvements and enhancements of the disclosed embodiments and other embodiments may be made based on the disclosure of this patent document. In addition, some of the components in the above-described embodiments may be deleted and implemented, and respective embodiments may be implemented in combination with each other.

What is claimed is:

1. A battery module comprising:
a cell stack including a plurality of battery cells;
a plurality of busbars electrically connected to the plurality of battery cells; and
a circuit board electrically connected to the plurality of busbars,
wherein the circuit board includes,
a plurality of extension portions extending in different directions; and
at least one overlapping portion in which at least two extension portions, among the plurality of extension portions, overlap.

2. The battery module of claim 1, wherein in the at least one overlapping portion, the circuit board has a folded shape folded at least once.

3. The battery module of claim 1, wherein the plurality of extension portions include,
a first extension portion disposed above the cell stack and extending in a first direction; and
a second extension portion extending in a second direction different from the first direction.

4. The battery module of claim 3, further including a support frame supporting the plurality of busbars,
wherein in the first extension portion, a first surface of the circuit board faces the support frame, and
in the second extension portion, a second surface of the circuit board, an opposite surface to the first surface, faces the support frame.

5. The battery module of claim 4, wherein the at least one overlapping portion further includes a first overlapping portion configured such that the first extension portion and the second extension portion overlap.

6. The battery module of claim 5, wherein in the first overlapping portion, the first extension portion and the second extension portion face each other in a direction perpendicular to the first surface.

7. The battery module of claim 4, wherein the first surface of the circuit board is provided with a circuit layer disposed thereon, and
the second surface of the circuit board is provided with an insulating layer disposed thereon.

8. The battery module of claim 3, wherein the plurality of extension portions further include a third extension portion to which a sensing terminal electrically connected to the plurality of busbars is connected.

9. The battery module of claim 8, wherein the at least one overlapping portion further includes a second overlapping portion in which the second extension portion and the third extension portion overlap.

10. The battery module of claim 9, wherein in the second overlapping portion, the circuit board overlaps three or more times.

11. The battery module of claim 9, wherein the battery module includes,
a plurality of busbar frames to which the plurality of busbars are coupled; and
a connecting frame connecting the plurality of busbar frames, and
the second overlapping portion faces one of the plurality of busbar frames.

12. The battery module of claim 8, wherein the sensing terminal includes a first coupling portion coupled with the circuit board and a second coupling portion coupled with at least one of the plurality of busbars.

13. The battery module of claim 12, wherein the first coupling portion is soldered to the circuit board, and
the second coupling portion is welded to at least one of the plurality of busbars.

14. The battery module of claim 8, wherein the circuit board further includes a temperature sensor disposed on the third extension portion.

15. The battery module of claim 14, further
comprising a support frame supporting the plurality of busbars,
wherein the support frame includes an avoidance portion avoiding the temperature sensor, and
at least a portion of the temperature sensor is accommodated in the avoidance portion and faces the cell stack.

16. The battery module of claim 1, further comprising an insulating member covering the overlapping portion of the circuit board and formed of an insulating material.

17. The battery module of claim 1, wherein the circuit board is a sensing circuit board to which a sensing member is connected, the sensing member including at least one of a temperature sensor for measuring temperature or a sensing terminal connected to the plurality of busbars and measuring voltage.

18. A busbar assembly comprising:
a support frame;
at least one busbar coupled to the support frame; and
a circuit board disposed in the support frame and electrically connected to the at least one busbar,
wherein the circuit board includes,
a first extension portion and a second extension portion extending in different directions from the support frame;
a third extension portion extending from at least one of the first extension portion or the second extension portion and connected to the at least one busbar; and
at least one overlapping portion provided by overlapping any two of the first extension portion, the second extension portion, or the third extension portion.

19. The busbar assembly of claim 18, wherein the support frame includes a plurality of busbar frames to which the at least one busbar is coupled and a connecting frame connecting the plurality of busbar frames to each other, and
the first extension portion and the second extension portion are disposed on the connecting frame, and the third extension portion is disposed on at least one of the plurality of busbar frames.

20. The busbar assembly of claim 18, wherein the third extension portion is extended in parallel with either the first extension portion or the second extension portion.
